(19) United States
(12) Patent Application Publication
(10) Pub. No.: US 2007/0230103 A1
(43) Pub. Date: Oct. 4, 2007

(54) Application of electronic components in printed products

(75) Inventors: Reinhard Baumann, Krailling (DE); Thomas Walther, Offenbach (DE); Arved Hubler, Chemnitz (DE)

Correspondence Address: LEYDIG VOIT & MAYER, LTD, TWO PRUDENTIAL PLAZA, SUITE 4900, 180 NORTH STETSON AVENUE, CHICAGO, IL, 60601-6731, US

(73) Assignees: MAN Roland Druckmaschinen AG, Offenbach (DE); printed systems GmbH, Chemnitz (DE)

(21) Appl. No.: 11/731,998

(22) Filed: Apr. 2, 2007

(30) Foreign Application Priority Data
Apr. 4, 2006 (DE) 102006016063.0
Feb. 14, 2007 (DE) 102007007269.6

(51) Int. Cl. H05K 5/00

(52) U.S. Cl. 361/683

(57) ABSTRACT

The invention provides a method and apparatus for integrating electronic components on conductor tracks as well as corresponding electronic components. With the invention, the electronic component can be applied with less precision on a printing material such as a substrate to be printed or a printed product. In a subsequent processing step, one or more printing units print conductor tracks. The conductor tracks are oriented through registration of the printing unit or the conveyor mechanism to the previously applied electronic component.

### FIELD OF THE INVENTION

The invention relates to a method and an apparatus for applying electronic components and conductor tracks to printed products and/or for producing tags with transponder technology and an electronic component.

### BACKGROUND OF THE INVENTION

A trend in the development of packaging and printed matter is to refine the packages and printed products not only in a visually appealing manner, but also to provide additional functionalities. Such additional functionalities can simplify product handling, increase forgery protection or product security and allow interaction of the consumer with the printed product or package. The most well known, but not only, example is transponder technology. However, additional functionalities can also be added to the printed product through a sensor, a switch, a display or a power supply.

Conductor tracks are required to connect the individual components to each other. Transponder technology requires antennas. Antennas and conductor tracks can be printed using conductive printing inks. Conductive inks can be metal-based printing inks and/or printing inks based on conductive polymers.

When producing RFID (radio frequency identification device) tags (i.e., transponder technology), electronic components that comprise a component of a transponder having an antenna are directly mounted or are mounted on an auxiliary carrier (e.g., straps). The electronic components can be applied on a web that is continuously advanced or advanced in discrete steps by a chip applicator. The chip applicator positions and mounts the electronic components or the auxiliary carrier and electronic components using known methods of bonding such as conductive or anisotropic bonding agents, so-called crimping (through mechanical anchoring) or by soldering onto the antenna. Antennas can also be applied by known methods of etching, stamping or printing onto the substrate. From the production methods used with so-called smartcards, mounting chips or components that carry electrical functionalities onto individual printed products is also known.

Printing a plurality of antennas with several copies on one sheet and then to separate the sheet into individual copies in a processing step (e.g., a stamping process) is disclosed in certain patent publications (e.g., WO 2005/078648). The antennas arranged on the individual copies can then be provided with a chip or a chip on an auxiliary carrier (strap) via a separate device. The disadvantage of this process is that the chip or chip and auxiliary carrier must be positioned very precisely on the antenna contacts. It is known that with RFID or transponder technology even a slightly off-center deviation of the chip relative to the antenna during mounting can lead to detuning and output losses of the RFID element or transponder. Because of the precise positioning that is required, the printed product must be fed in a very accurate manner and a complicated method must be used to position the chip. The positioning of the chip or the chip and auxiliary carrier is therefore—just due to the overall size—the task that most significantly impacts the achievable production rate of printed products with RFID or transponder technology.

A second production rate restriction is that the chip or the auxiliary carrier and chip on this auxiliary carrier must enter into a close connection with the contacts of the antenna. In particular, the chip or the auxiliary carrier with chip is mounted on the antenna using a conductive or anisotropic adhesive. For this purpose, the chip or auxiliary carrier and chip must be pressed against the antenna contacts for a certain length of time with the bonding agent. This significantly slows the process and makes continuous and economical production difficult.

At least using known technologies, the process of applying a chip or a chip on an auxiliary carrier is significantly slower (by up to a factor of 10) than other printing and subsequent processing steps performed in modern printing plants. As a result, the chip application process can quickly become a bottleneck for the entire production process.

### BRIEF SUMMARY OF THE INVENTION

In view of the foregoing, a general object of the present invention is to provide a quick and operationally safe application and connection method for electronic components with conductor tracks or antenna structures. Another object of the invention is to provide electronic components and a suitable apparatus for processing such electronic components.

The key aspect of the invention is applying an electronic component onto a printing material, such as a substrate to be printed or a printed material, and producing conductive connections to circuits or alternatively producing such circuits themselves in contact with the electronic components through a printing process after application of the electronic component. Chips for transponders in RFID systems, for example, can comprise the electronic components.

The absolute positioning of the transponder, which includes at least an antenna and a chip on the printed product, can be varied within tight limits. As is generally known by those skilled in the art, an advantage of RFID or transponder technology is that visual contact with the reading device such as is necessary with a barcode is not required. Thus, the transponder can be placed inside a package. Additionally, with a RFID tag (also referred to as a “smart label”), the absolute position of the transponder within the limits of the tag is not an issue.

Since the exact application of the chip or auxiliary carrier and chip on an antenna can be considered the most important factor limiting output in a production process, significant advantages can be obtained by simplifying this step. A first approach for simplifying the chip application step is by eliminating the need for precise positioning. Another way to simplify the application process is by eliminating the complicated bonding process using conductive or anisotropic adhesives with long curing times to produce contacts between the chip or the auxiliary carrier and chip.

According to the invention, the production of a transponder is accelerated by bonding the chip or the auxiliary carrier and chip directly on the material to be printed or the printed product. In such case, the bonding agent only needs to provide sufficient adhesion to the material to be printed or the printed product. After the application of the chip or the auxiliary carrier and chip, the position of the chip or auxiliary carrier and chip is determined by a sensor system, preferably a camera. A printing or stamping system for printing the antenna structure is arranged after the application process and is controlled so that the contacts of the chip or auxiliary carrier are covered with a conductive printing ink or blocking foil so that contact between the chip or the auxiliary carrier and chip and the antenna structure is ensured.

An important advantage of such an arrangement or process is that the printing or stamping system can be adjusted dynamically in the peripheral, side or diagonal registers so that the antennas are printed or stamped within tight limits at the precise desired angle and position relative to the previously applied chip or chip on an auxiliary carrier. This method can be easily transferred from the production of transponders to other applications that involve connection of an electronic component to a conductor track.

Due to the very low accuracy required for the positioning of the chip or auxiliary carrier and chip, the application process can be performed significantly more quickly. As a result, higher throughput can be achieved by reducing the production bottleneck at the chip application stage.

### BRIEF DESCRIPTION OF THE SEVERAL VIEWS OF THE DRAWINGS

FIG. 1 is a schematic side view of an illustrative auxiliary carrier for a chip fixed on a material to be printed with components of an antenna of a RFID transponder printed or stamped over the contact areas of the auxiliary carrier according to the invention.

FIG. 2 is a schematic side view of an illustrative chip fixed on a material to be printed with components of an antenna of a RFID transponder printed or stamped over the contact areas of the chip according to the invention.

FIG. 3 is a schematic side view of an illustrative printing device according to the invention with roller feeding for adhering a chip or auxiliary carrier and chip to a roll web.

FIG. 4 is a schematic side view of an alternative embodiment of a printing device according to FIG. 3 in which longitudinal register adjustment can be achieved via an individual drive of the printing device.

FIG. 5 is a schematic side view of another alternative embodiment of a printing device according to FIG. 3 in which an additional roll web can be joined to the roll web with the attached chip.

FIG. 6 is a schematic side view of an illustrative sheet fed printing device for applying electronic components onto a sheet according to the invention.

FIG. 7 is a schematic side view of an alternative embodiment of a sheet fed printing device according to FIG. 6 in which the conveyor mechanism is divided into two sections.

### DETAILED DESCRIPTION OF THE INVENTION

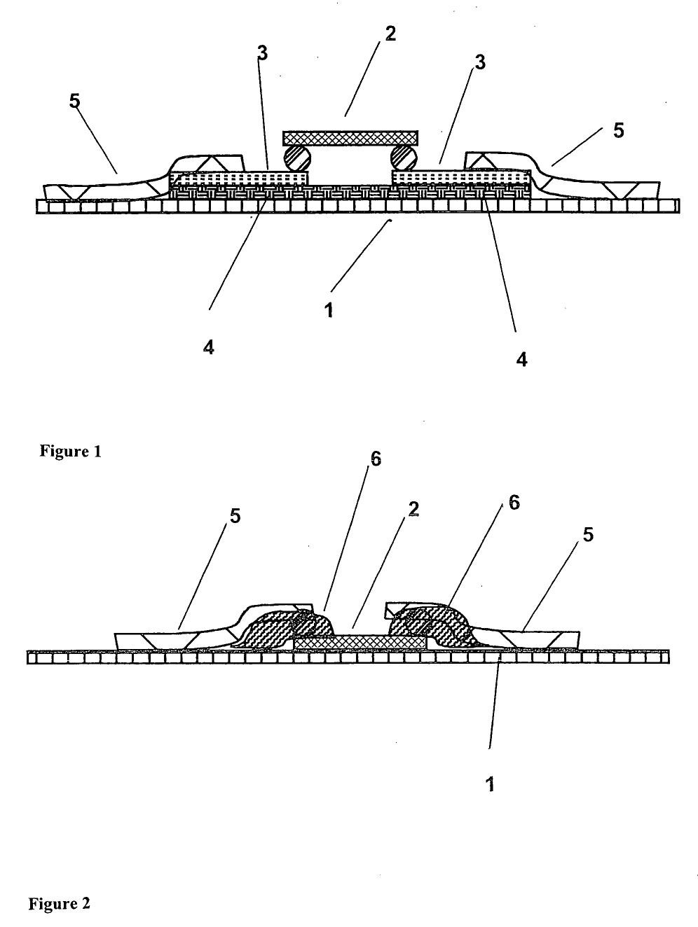

Referring to FIG. 1 of the drawings, an auxiliary carrier 4 is shown that has been fixed on a printing material or material to be printed 1 using a bonding agent or some other suitable method. The auxiliary carrier 4 has conductive contact areas 3 that are in contact with the contact areas of a chip 2. In a second processing step, conductive structures 5, which in this case are components of an antenna of an RFID transponder, have been printed or stamped over the contact areas 3 of the auxiliary carrier 4. It is significant that, in contrast to the typical procedure, the contact areas are located not on the print side, but instead on the side of the auxiliary carrier and chip facing away from the print side in order to allow printing.

An arrangement of an individual chip (i.e., which is not located on an auxiliary carrier) on material to be printed 1 is shown in FIG. 2. The contacts of the chip 2 can face towards or away from the material to be printed 1. An arrangement in which the contacts face away from the material to be printed 1 is preferred. If necessary, the chip 2 can be fixed on the material to be printed with a conductive bonding agent 6. A conductive layer 5, which in this case is a component of an antenna or a conductor track, is printed on the contacts of the chip 2 and/or over any layer of conductive bonding agent 6 in a printing step following the application process.

The printing unit for printing the conductive layers 5 can be an offset, a flexographic or a roller printing unit. The printing unit also can be a rotary screen printing unit or a flat-bed screen printing unit. Moreover, the printing unit can be a non-impact printer, for example, an inkjet printer. A characteristic feature of the printing unit is that the printing image can be moved from copy to copy in a highly dynamic manner relative to the material to be printed in the longitudinal, side and diagonal registers so that the printing image can be oriented to match the previously applied chip or auxiliary carrier and chip. With rotary printing systems, this characteristic feature can be achieved by locating the entire printing unit on a plate that is shifted by quick adjustment devices. The longitudinal register adjustment can be achieved, for example, by providing the entire printing unit or the form cylinder of the printing unit with a drive that can be controlled in a highly dynamic manner. Thus, in the longitudinal direction (i.e., feeding direction) the start point of the printing is completely arbitrary. A side register adjustment can also be performed by adjusting several cylinders or the entire printing unit laterally. The diagonal register can be adjusted by crossing the printing unit or individual cylinders or cylinder groups laterally with quick adjustment drives. A non-rotary printing system, like a flat-bed screen printing system or an inkjet print head or an array of inkjet print heads, can also be offset by quick drives. With an array of inkjet print heads, the arrangement of the print image relative to the electronic component can also be determined using software with the nozzles of the ink sprayers being activated so that the print image is always arranged in substantially the same manner relative to the electronic component.

Piezoelectric actuators, linear drives or actuators of any other suitable type can be used as the adjustment drives. The longitudinal register can be performed in the proven form with individual drives of the printing unit or individual cylinders.

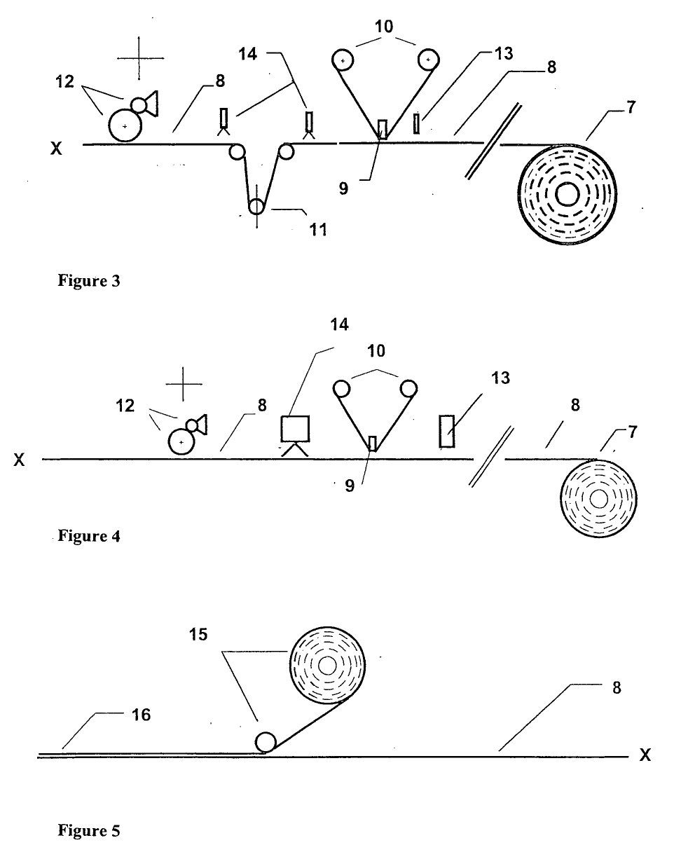

A printing device utilizing roller guidance is illustrated in FIG. 3. In the printing device of FIG. 3, the roll web 8 unrolls from a storage roller 7 and optionally is then printed (not shown). The roll web can then be fed to an adhesive dispenser 13 which provides the web with a bonding agent for adhesion of the chip 2 or the auxiliary carrier 4 and chip 2. Alternatively, the auxiliary carrier belt 10 and chip 2 can also be provided with or be a bonding agent. The roll web is then fed to the applicator device 9 which places or fixes the chip 2 or the auxiliary carrier 4 and chip 2 on the roll web. The position of the applied chip 2 or the auxiliary carrier is then detected by a suitable sensor 14 or a plurality of suitable sensors 14. A suitable sensor 14 could be, for example, a camera system. In the embodiment of FIG. 3, the longitudinal positioning of the printing unit 12 relative to the determined chip position is performed by a dancer roller 11 or a dancer roller group. Through movement of the dancer roller 11, the chip is positioned on the roll web 8 in the transport direction so that the conductor tracks 5 or antenna tracks 5 come in contact at the provided positions with the chip 2 or auxiliary carrier 4 and chip 2. The diagonal and side registers can be adjusted in a known manner or by quick adjustment drives in the printing unit 12.

An alternative embodiment in which the longitudinal register adjustment by the dancer roller 11 is eliminated is shown in FIG. 4. In this embodiment, the longitudinal register can be accomplished via an individual drive of the printing unit 12.

Additional processing steps can be added to the devices for forming a transponder on a roll web 8 according to the present invention, such as those shown in FIGS. 3 and 4. For example, the roll web 8 can be divided, stamped, grooved, folded, or re-rolled in sections. In FIG. 5, the roll web 8 with the transponder arranged on the web is shown being joined and connected to another roll web 16. The additional roll web 16 is unrolled from an unwinding station 15 with a storage roller and can be joined and connected to the fed roll web 8 with the transponder in a suitable manner. The additional roll web 16 can be used to protect the underlying transponder. The additional roll web 16 can be printed with information or can be composed of an unprinted roll web.

The present invention also encompasses devices that apply transponder components onto a sheet. With respect to the present invention, sheets can be printing or paper sheets, collapsible cardboard box sections, folded and/or stitched products, books or films. Thus, with respect to the present invention, the term “sheet” includes all printed substrates and printed products that do not exist as roll webs. Moreover, with respect to transporting the sheets along a path, rotating belts (with and without suction), gripper carriages, sleds, chains, suction bands, Velcro strips, or similar devices can be used as conveyor mechanisms in devices according to the invention.

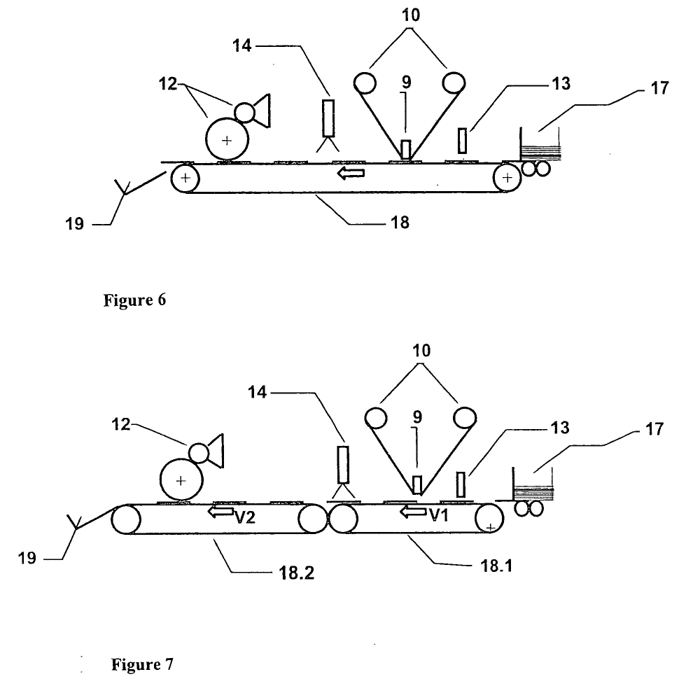

Referring to FIG. 6 of the drawings, a sheet fed device according to the invention is shown in which a sheet is laid onto a conveyor mechanism, in this case a rotating belt 18, by an inserter or feeder 17. The sheet is optionally first fed to an adhesive dispenser 13 that applies the bonding agent for fixing the chip 2 or auxiliary carrier 4 and chip 2 onto the sheet. Alternatively, the chip 2 or the auxiliary carrier 4 can be provided with a bonding-agent layer before it is dispensed. After this processing step, the sheet comes to an applicator device 9 which dispenses the chip 2 or the auxiliary carrier 4 and chip 2 onto the sheet. As the next processing step, the position of the chip 2 or auxiliary carrier 4 and chip 2 on the sheet is determined by a suitable sensor system 14. In a preferred embodiment, the sensor system 14 is a camera. The sheet is then fed to a printing unit 12 which allows a highly dynamic adjustment of the peripheral, side, and diagonal registers from sheet to sheet. A significant characteristic relative to the sheet flow in the embodiment of FIG. 6 is that the distance between the individual sheets is largely equidistant.

In the embodiment of FIG. 7, the conveyor mechanism 18 is divided into two sub-sections (18.1 and 18.2), in this case shown as two separate rotating belts. After application of the chip 2 or the auxiliary carrier 4 and chip 2 onto the sheet via the applicator device 9, the position of the chip 2 or the auxiliary carrier 4 and chip 2 on the sheet is determined and the obtained values are used to control the second conveyor mechanism section 18.2. By adjusting the speed of the second conveyor mechanism 18.2, the sheet can be fed earlier or later to the printing device 12. In this way, errors in positioning the chip 2 or the auxiliary carrier 4 and chip 2 in the conveyor direction can be corrected. The lateral adjustment of the printing unit 12 is achieved using highly dynamic adjustment of the side and diagonal registers. An important aspect of this configuration is that the sheets do not have to be provided at equidistant intervals in the conveyance direction and instead can be provided at variable intervals.

The present invention has been explained in the context of the RFID field. However, those skilled in the art will appreciate that the applied electronic component does not have to be a chip 2. Alternatively, the applied electronic component can be a sensor, a display, a battery, a logic unit, or a switch. The operation of the illustrated embodiment remains the same, only instead of the chip 2, another electronic component or element that requires a conductive connection is applied.

### LIST OF REFERENCE SYMBOLS

1 Material to be printed
2 Chip
3 Contact area
4 Auxiliary carrier
5 Conductive printed layer
6 Conductive or anisotropic adhesive
7 Storage roller
8 Roll web
9 Applicator
10 Storage roller for auxiliary carrier belt
11 Dancer roller
12 Printing device
13 Adhesive dispenser
14 Sensor
15 Unwinding device cover web
16 Cover web
17 Inserter/feeder
18 Conveying means
18.1 Sub-section conveying means
18.2 Sub-section conveying means
19 Delivery unit/stacker

1. A method of applying electronic components and conductor tracks to a printing material using a device for feeding electronic components to the printing material, the method comprising the steps of:
directly bonding an electronic component containing an electrical circuit or an auxiliary carrier with an electronic component on the printing material;
determining with a sensor system the position of the electronic component or the auxiliary carrier with the electronic component after application of the electronic component or the auxiliary carrier with the electronic component on the printing material; and
applying a conductive structure comprising a conductive printing ink or a blocking foil using a printing or stamping system such that the conductive structure covers contacts of the electronic component or contacts of the auxiliary carrier to ensure complete electrical contact between the electronic component or auxiliary carrier with the electronic component and the conductive structure.

2. The method according to claim 1 wherein the printing or stamping system is dynamically adjustable and the conductive structure is printed or stamped at an exact angle and position relative to a previously applied electronic component or electronic component on an auxiliary carrier.

3. The method according to claim 1 wherein the conductive structure is arranged to provide an electrically conductive connection of the electronic component or the auxiliary carrier with the electronic component to a conductor track.

4. An electronic element comprising:
an electronic component or an auxiliary carrier with an electronic component arranged on a supporting substrate, the electronic component for the auxiliary carrier having contact areas; and
conductive structures printed or stamped on the contact areas of the electronic component or the auxiliary carrier.

5. The electronic element according to claim 4 wherein the contact areas of the electronic component or the auxiliary carrier are arranged on a side of the electronic component or the auxiliary carrier facing away from a print side of the supporting substrate.

6. The electronic element according to claim 5 wherein the electronic component or the auxiliary carrier is fixed on the substrate via a conductive bonding agent.

7. An apparatus for producing an electronic component comprising:
a transport system for a printing material on which an electronic component or an auxiliary carrier with an electronic component is arranged; and
a printing unit arranged in a transport path of the transport system for printing a pattern of one or more conductive layers in contact with the electronic component or auxiliary carrier with electronic component on the printing material.

8. The apparatus according to claim 7 wherein the printing unit includes an adjusting mechanism for moving the conductive layer pattern in a highly dynamic manner relative to the material to be printed in terms of a longitudinal, side and diagonal register between successive printings of the pattern of conductive layers.

9. The apparatus according to claim 7 wherein the printing unit includes a mechanism for orienting the conductive layer pattern to match a previously applied electronic component or auxiliary carrier with electronic component.

10. The apparatus according to claim 7 wherein the printing unit is arranged on a platform in a rotary printing system and the platform is movable relative to the printing material using a plurality of quick adjustment mechanisms.

11. The apparatus according to claim 10 wherein the quick adjustment mechanisms comprise actuators.

12. The apparatus according to claim 10 wherein the printing unit includes a plurality of cylinders each having an individual drive and the individual drives are configured to adjust a longitudinal register.

13. The apparatus according to claim 7 wherein the printing unit is part of a rotary printing system and parts of the printing unit are adjustable relative to each other and movable using a plurality of quick adjustment mechanisms relative to the printing material.

14. The apparatus according to claim 13 wherein the quick adjustment mechanisms comprise actuators.

15. The apparatus according to claim 13 wherein the printing unit includes a plurality of cylinders each having an individual drive and the individual drives are configured to adjust a longitudinal register.

16. The apparatus according to claim 7 wherein the printing material comprises a printing web and further including a roller feeder for feeding the printing web to the printing unit and an adhesive dispenser for applying a bonding agent in an exact position on the printing web to secure an electronic components or an auxiliary carriers with electronic component in an exact position on the printing web.

17. The apparatus according to claim 8 wherein one or more sensors are provided for detecting a position of the electronic component or the auxiliary carrier with electronic component arranged on the printing material and the adjustment mechanism is controllable based the position detected by the sensors.

18. The apparatus according to claim 17 wherein the one more sensors comprise a camera system.

19. The apparatus according to claim 17 wherein the adjustment mechanism comprises a dancer roller.

20. The apparatus according to claim 7 further including a further processing unit arranged in a downstream direction relative to a transport direction of the printing material from the printing unit.

21. The apparatus according to claim 7 wherein the printing material comprises a sheet.

22. The apparatus according to claim 21 wherein the transport system is configured to transport a sheet.
